(19) United States
(12) Patent Application Publication
(10) Pub. No.: US 2013/0214640 A1
(43) Pub. Date: Aug. 22, 2013

(54) SURFACE ACOUSTIC WAVE DEVICE

(71) Applicant: Murata Manufacturing Co., Ltd., (US)

(72) Inventor: Hisashi YAMAZAKI, Nagaokakyo-shi (JP)

(73) Assignee: Murata Manufacturing Co., Ltd., Nagaokakyo-shi (JP)

(21) Appl. No.: 13/855,066

(22) Filed: Apr. 2, 2013

Related U.S. Application Data
(63) Continuation of application No. PCT/JP2011/072932, filed on Oct. 5, 2011.

(30) Foreign Application Priority Data
Oct. 15, 2010 (JP) 2010-232697

(51) Int. Cl. H01L 41/047

(52) U.S. Cl. CPC H01L 41/0475
USPC 310/313 B

(57) ABSTRACT

A surface acoustic wave device having high heat radiation performance is provided. A surface acoustic wave device includes a piezoelectric substrate, IDT electrodes, a cover, and wiring lines. The IDT electrodes are arranged on a main surface of the piezoelectric substrate. The cover is joined to the main surface. The wiring lines extend to join portions of the main surface and the cover. The cover is provided with through-holes facing the wiring lines, respectively. The surface acoustic wave device further includes under-bump metals arranged in the through-holes, respectively, and bumps arranged on the under-bump metals, respectively. In a plan view, each of the under-bump metals is provided in a region larger than a joint portion of each of the under-bump metals and the corresponding one of the bumps

### BACKGROUND OF THE INVENTION

1. Field of the Invention

The present invention relates to a surface acoustic wave device.

2. Description of the Related Art

In recent years, a surface acoustic wave device using surface acoustic waves has been frequently used as a resonator or a filter. A surface acoustic wave device includes a piezoelectric substrate and IDT electrodes formed on the piezoelectric substrate. When a surface acoustic wave excites these IDT electrodes and propagates along a surface of the piezoelectric substrate, a function is manifested. Thus, if the state of the surface of the piezoelectric substrate is changed, a characteristic to be manifested is substantially changed. In a surface acoustic wave device, therefore, the surface of the piezoelectric substrate is covered by a cover to thereby suppress a change in characteristics due to disturbance, as described in Japanese Unexamined Patent Application Publication No. 2009-247012, for example.

In the surface acoustic wave device including the cover covering the surface of the piezoelectric substrate, it is common to supply electric power to the internal IDT electrodes by using under-bump metals piecing through the cover and bumps disposed on the under-bump metals.

In the surface acoustic wave device, if the surface acoustic wave is excited in the IDT electrodes, the IDT electrodes generate heat. The heat generation of the IDT electrodes results in an increase in temperature inside the cover, and may cause a change in a characteristic to be obtained. Therefore, enhancing heat radiation performance of the surface acoustic wave device is an issue.

### SUMMARY OF THE INVENTION

Preferred embodiments of the present invention provide a surface acoustic wave device having high heat radiation performance.

A surface acoustic wave device according to a preferred embodiment of the present invention includes a piezoelectric substrate, an Inter-Digital Transducer (IDT) electrode, a cover, and a wiring line. The piezoelectric substrate includes a main surface. The IDT electrode is arranged on the main surface of the piezoelectric substrate. The cover is joined to the main surface. The cover defines a sealing space above a region of the main surface formed with the IDT electrode. The wiring line is connected to the IDT electrode. The wiring line extends to a joint portion of the main surface and the cover. The cover is provided with a through-hole facing the wiring line. The surface acoustic wave device according to a preferred embodiment of the present invention further includes an under-bump metal provided in the through-hole and a bump arranged on the under-bump metal. In a plan view, the under-bump metal is provided in a region larger than a joint portion of the under-bump metal and the corresponding bump.

In a specific aspect of the surface acoustic wave device according to a preferred embodiment of the present invention, at least a portion of the under-bump metal is arranged to extend to a region not provided with the bump. According to this configuration, it is possible to more effectively improve heat radiation performance of the surface acoustic wave device.

In another specific aspect of the surface acoustic wave device according to a preferred embodiment of the present invention, the surface acoustic wave device further includes an insulating layer covering a portion of the under-bump metal excluding the joint region of the under-bump metal jointed to the bump. According to this configuration, it is possible to significantly reduce and prevent undesired wet spreading of the bump.

In a still another specific aspect of the surface acoustic wave device according to a preferred embodiment of the present invention, the under-bump metal includes a bottom portion on the side of the piezoelectric substrate and an upper portion which is located closer to the bump than the bottom portion is. In a plan view, the bottom portion is larger than the upper portion.

According to a preferred embodiment of the present invention, in a plan view, the under-bump metal is provided in a region larger than a region in which the under-bump metal and the corresponding bump are jointed together. It is therefore possible to improve heat radiation performance of the surface acoustic wave device.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan view of a surface acoustic wave device according to a first preferred embodiment of the present invention.

FIG. 2 is a schematic cross-sectional view along a line II-II in FIG. 1.

FIG. 3 is a schematic cross-sectional view of an elastic wave device according to a comparative example.

FIG. 4 is a schematic cross-sectional view of an elastic wave device according to a second preferred embodiment of the present invention.

### DETAILED DESCRIPTION OF THE PREFERRED EMBODIMENTS

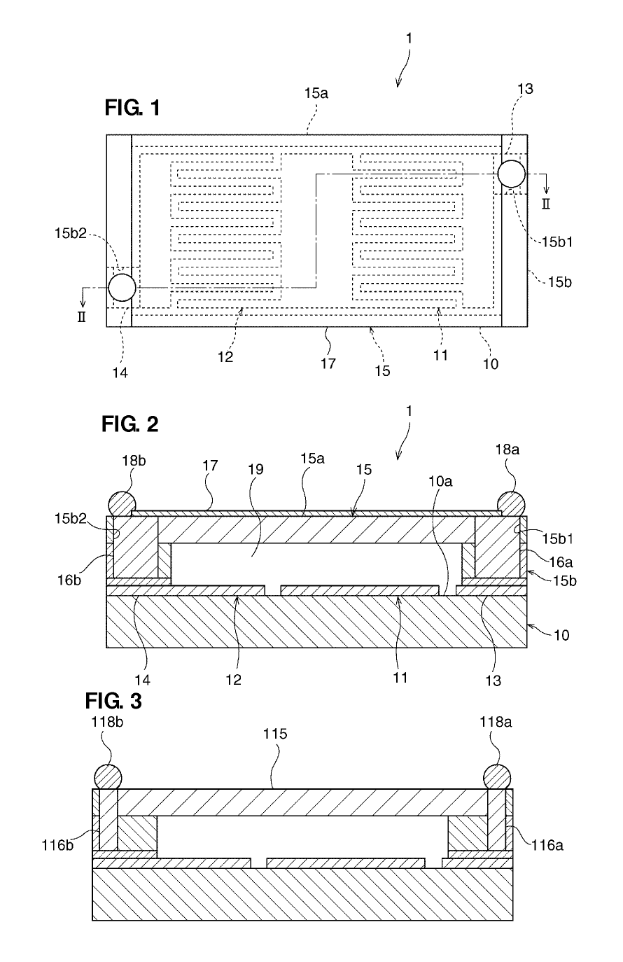

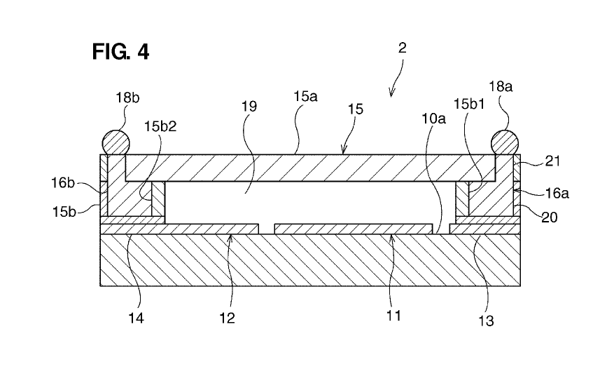

Preferred embodiments of the present invention will be described below with reference to surface acoustic wave devices 1 and 2 illustrated in FIGS. 1 and 4, respectively, as examples. The surface acoustic wave devices 1 and 2, however, are merely exemplifications of preferred embodiments of the present invention. A surface acoustic wave device according to the present invention is not limited at all to the surface acoustic wave devices 1 and 2.

### First Preferred Embodiment

FIG. 1 is a schematic plan view of a surface acoustic wave device according to a first preferred embodiment of the present invention. FIG. 2 is a schematic cross-sectional view along a line II-II in FIG. 1.

The surface acoustic wave device 1 illustrated in FIGS. 1 and 2 is a surface acoustic wave resonator. A surface acoustic wave device according to preferred embodiments of the present invention, however, is not limited to the surface acoustic wave resonator. A surface acoustic wave device according to preferred embodiments of the present invention may be a surface acoustic wave filter device, or may be a surface acoustic wave branching filter, such as a surface acoustic wave duplexer and a surface acoustic wave triplexer, for example.

As illustrated in FIGS. 1 and 2, the surface acoustic wave device 1 includes a piezoelectric substrate 10. The piezoelectric substrate 10 may preferably be made of, for example, a LiNbO₃ substrate, a LiTaO₃ substrate, a crystal substrate, or the like.

Two series-connected IDT electrodes 11 and 12 are arranged on a main surface 10a of the piezoelectric substrate 10. Further, wiring lines 13 and 14 connected to the IDT electrodes 11 and 12, respectively, are preferably arranged on the main surface 10a. The IDT electrodes 11 and 12 and the wiring lines 13 and 14 may preferably be made of, for example, a metal selected from a group of Al, Pt, Au, Ag, Cu, Ni, Ti, Cr, and Pd or an alloy including one or more metals selected from the group of Al, Pt, Au, Ag, Cu, Ni, Ti, Cr, and Pd. Further, the IDT electrodes 11 and 12 and the wiring lines 13 and 14 may be defined by, for example, a laminate of a plurality of conductive layers made of the above-described metal or alloy.

A cover 15 is preferably provided on the main surface 10a of the piezoelectric substrate 10. The cover 15 includes a plate-shaped cover body 15a which is located above a region of the main surface 10a provided with the IDT electrodes 11 and 12, and frame portions 15b which are provided to peripheral portions of the cover body 15a and project toward the piezoelectric substrate 10 more than the cover body 15a does. With these frame portions 15b joined to the main surface 10a, the cover 15 is fixed to the main surface 10a. A sealing space 19 defined by the cover 15 and the piezoelectric substrate 10 is arranged between the cover body 15a and the main surface 10a.

The above-described wiring lines 13 and 14 extend to joint portions of the frame portions 15b and the main surface 10a. In other words, respective leading end portions of the wiring lines 13 and 14 are preferably located under the frame portions 15b in a plan view. The frame portions 15b are preferably provided with through-holes 15b1 and 15b2 facing the leading end portion of the wiring line 13 and the leading end portion of the wiring line 14, respectively. These through-holes 15b1 and 15b2 are respectively provided with under-bump metals 16a and 16b to be connected to the wiring lines 13 and 14, respectively. The respective upper surfaces of the under-bump metals 16a and 16b are on substantially the same plane as the cover body 15a. A portion of the upper surface of each of these under-bump metals 16a and 16b is preferably covered by an insulating layer 17 disposed on the cover body 15a, and only a portion of the upper surface is exposed. Further, bumps 18a and 18b are preferably arranged on the respective exposed portions of the under-bump metals 16a and 16b. That is, portions of the under-bump metals 16a and 16b excluding joint regions of the under-bump metals 16a and 16b respectively joined to the bumps 18a and 18b are covered by the insulating layer 17. Therefore, undesired wet spreading of the bumps 18a and 18b is effectively suppressed and prevented.

The surface acoustic wave device 1 of the present preferred embodiment is preferably produced in, for example, the following manner. A wafer made of a piezoelectric material is first prepared. Then, a plurality of surface acoustic wave resonator portions including the IDT electrodes 11 and 12 and the wiring lines 13 and 14 are preferably formed on a main surface of the wafer by, for example, a vapor deposition-liftoff method. A photosensitive polyimide-based resin is applied onto the plurality of surface acoustic wave resonator portions. The applied polyimide-based resin is preferably patterned by a photolithography method, to form the plurality of frame portions 15b facing to the plurality of surface acoustic wave resonator portions and portions of the through-holes 15b1 and 15b2 provided in the frame portions 15b. A photosensitive epoxy-based resin film is attached onto the plurality of frame portions 15b. The epoxy-based resin film is preferably patterned by a photolithography method, to form the cover body 15a facing to the plurality of surface acoustic wave resonator portions and the remaining portions of the through-holes 15b1 and 15b2 provided in the cover body 15a. The under-bump metals 16a and 16b made of Ni—Au are preferably formed by electrolytic plating in the through-holes 15b1 and 15b2, respectively. The insulating layer 17 is formed by Spin-On-Glass (SOG) on the cover body 15a and the upper surfaces of the under-bump metals 16a and 16b. The insulating layer 17 is dry-etched to expose only a portion of the upper surface of each of the under-bump metals 16a and 16b. A Sn—Ag—Cu-based solder is preferably printed on a portion of the upper surface of each of the under-bump metals 16a and 16b so as to form the bumps 18a and 18b. Finally, the wafer is diced to produce the ditto surface acoustic wave device 1.

The material of the cover 15 is not particularly limited, as long as the material is an electrically insulating material. The cover 15 may preferably be made of, for example, an imide-based resin or an amide-based resin. Further, the cover 15 may be made of a non-photosensitive material. In that case, it is preferred that the through-holes 15b1 and 15b2 be formed by laser or etching. The material of the under-bump metals 16a and 16b and the bumps 18a and 18b is not particularly limited, as long as the material is an electrically conductive material. The insulating layer 17 may preferably be made of an inorganic material, such as, for example, SOG and silicon oxide, a heat-resistant resin, and so forth.

Meanwhile, as illustrated in FIG. 3, each of under-bump metals 116a and 116b is normally arranged such that the cross-sectional area thereof is equal to the area of a joint portion of each of the under-bump metals 116a and 116b and the corresponding one of bumps 118a and 118b. In this case, however, the under-bump metals 116a and 116b higher in heat conductivity than a cover 115 have a small cross-sectional area. Therefore, heat radiation via the under-bump metals 116a and 116b is not effectively produced.

Meanwhile, according to the present preferred embodiment, in a plan view (as viewed in the direction of a normal of the main surface 10a), each of the under-bump metals 16a and 16b is provided in a region larger than the joint portion of each of the under-bump metals 16a and 16b and the corresponding one of the bumps 18a and 18b. That is, the cross-sectional area of at least a portion of each of the under-bump metals 16a and 16b is preferably larger than the area of the joint portion of each of the under-bump metals 16a and 16b and the corresponding one of the bumps 18a and 18b. In the surface acoustic wave device 1, therefore, the heat of the IDT electrodes 11 and 12 is effectively radiated via the under-bump metals 16a and 16b, which have a high heat conductivity. Accordingly, the surface acoustic wave device 1 has superior heat radiation performance.

Further, in the present preferred embodiment, the cross-sectional area of the entirety of each of the under-bump metals 16a and 16b is larger than the area of the joint portion of each of the under-bump metals 16a and 16b and the corresponding one of the bumps 18a and 18b. Accordingly, more superior heat radiation performance is realized.

Further, in the present preferred embodiment, at least a portion, specifically the entirety, of each of the under-bump metals 16a and 16b is preferably arranged to extend to a region not provided with the bumps 18a and 18b. It is therefore possible to additionally increase the cross-sectional area of at least a portion of each of the under-bump metals 16a and 16b. Accordingly, further superior heat radiation performance is realized.

### Second Preferred Embodiment

FIG. 4 is a schematic cross-sectional view of an elastic wave device according to a second preferred embodiment of the present invention.

The surface acoustic wave device 2 of the present preferred embodiment is different from the surface acoustic wave device 1 of the foregoing first preferred embodiment in the absence of the insulating layer 17 and the shape of the under-bump metals 16a and 16b.

In the present preferred embodiment, each of the under-bump metals 16a and 16b preferably includes a bottom portion 20 on the side of the piezoelectric substrate 10 and an upper portion 21 on the side of the bumps 18a and 18b. In a plan view, the bottom portion 20 is larger than the upper portion 21. Specifically, the cross-sectional area of the upper portion 21 is substantially the same as the area of the joint portion of each of the under-bump metals 16a and 16b and the corresponding one of the bumps 18a and 18b. Meanwhile, the cross-sectional area of the bottom portion 20 is preferably larger than the area of the joint portion of each of the under-bump metals 16a and 16b and the corresponding one of the bumps 18a and 18b. Also in this case, it is possible to realize superior heat radiation performance.

As described above, the surface acoustic wave device 2 of the present preferred embodiment does not include the insulating layer 17, and thus is capable of reducing the material cost and processes more than in the surface acoustic wave device 1 of the first preferred embodiment and being manufactured at lower cost.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A surface acoustic wave device comprising:
a piezoelectric substrate including a main surface;
an inter-digital transducer electrode arranged on the main surface of the piezoelectric substrate;
a cover joined to the main surface, and defining a sealing space above a region of the main surface provided with the inter-digital transducer electrode; and
a wiring line connected to the inter-digital transducer electrode, and extending to a joint portion of the main surface and the cover; wherein
the cover is provided with a through-hole facing the wiring line; and
the surface acoustic wave device further comprises:
an under-bump metal arranged in the through-hole; and
a bump arranged on the under-bump metal; and
in a plan view, the under-bump metal is provided in a region larger than a joint portion of the under-bump metal and the corresponding bump.

2. The surface acoustic wave device described in claim 1, wherein at least a portion of the under-bump metal is arranged to extend to a region not provided with the bump.

3. The surface acoustic wave device described in claim 1, further comprising an insulating layer covering a portion of the under-bump metal excluding the joint region of the under-bump metal joined to the bump.

4. The surface acoustic wave device described in claim 1, wherein
the under-bump metal includes a bottom portion on a side of the piezoelectric substrate and an upper portion which is located closer to the bump than the bottom portion is; and
in a plan view, the bottom portion is larger than the upper portion.

5. The surface acoustic wave device described in claim 1, wherein the piezoelectric substrate is made of a LiNbO₃ substrate, a LiTaO₃ substrate, or a crystal substrate.

6. The surface acoustic wave device described in claim 1, wherein the wiring line is made of a metal selected from Al, Pt, Au, Ag, Cu, Ni, Ti, Cr, and Pd or an alloy including one or more metals selected from Al, Pt, Au, Ag, Cu, Ni, Ti, Cr, and Pd.

7. The surface acoustic wave device described in claim 1, wherein the cover includes:
a plate-shaped cover body which is located above a region of the main surface provided with the inter-digital transducer electrode; and
a frame portion which is provided to a peripheral portion of the cover body and which projects toward the piezoelectric substrate more than the plate-shaped cover body does.

8. The surface acoustic wave device described in claim 7, wherein the through hole is arranged in the frame portion.

9. The surface acoustic wave device described in claim 1, wherein the under-bump metal is made of Ni—Au.

10. The surface acoustic wave device described in claim 1, wherein the bumps are made of Sn—Ag—Cu-based solder.

11. The surface acoustic wave device described in claim 3, wherein the insulating layer is made of Spin-On-Glass, Spin-On-Glass and silicon oxide, or a heat-resistant resin.

12. The surface acoustic wave device described in claim 1, wherein the cover is made of an electrically insulating material.

13. The surface acoustic wave device described in claim 12, wherein the cover is made of imide-based resin or amide-based resin.

14. The surface acoustic wave device described in claim 4, wherein a cross-sectional area of the bottom portion is larger than an area of the joint portion of the under-bump metal and the bump.

15. A surface acoustic wave device comprising:
a piezoelectric substrate including a main surface;
a plurality of inter-digital transducer electrodes arranged on the main surface of the piezoelectric substrate;
a cover joined to the main surface, and defining a sealing space above a region of the main surface provided with the plurality of inter-digital transducer electrodes; and
a plurality of wiring lines connected to the plurality of inter-digital transducer electrodes, and extending to a plurality of joint portions of the main surface and the cover; wherein
the cover is provided with a plurality of through-holes facing the wiring line; and
the surface acoustic wave device further comprises:
a plurality of under-bump metals arranged in respective ones of the plurality of through-holes; and
a plurality of bumps arranged on respective ones of the plurality of the plurality of under-bump metals; and
in a plan view, the plurality of under-bump metals is provided in a region larger than a joint portion of the plurality of under-bump metals and the corresponding ones of the plurality of bumps.

16. The surface acoustic wave device described in claim 15, wherein at least a portion of each of the plurality of under-bump metals is arranged to extend to regions not provided with the plurality of bumps.

17. The surface acoustic wave device described in claim 15, further comprising an insulating layer covering a portion of the plurality of under-bump metals excluding the plurality of joint regions of the plurality of under-bump metals joined to the plurality of bumps.

18. The surface acoustic wave device described in claim 15, wherein each of the plurality of under-bump metals includes a bottom portion on a side of the piezoelectric substrate and an upper portion on a side of a respective one of the plurality of bumps, the bottom portion is larger than the upper portion in a plan view.

19. The surface acoustic wave device described in claim 15, wherein the cover includes:
a plate-shaped cover body which is located above a region of the main surface provided with the plurality of inter-digital transducer electrodes; and
a plurality of frame portions which are provided to peripheral portions of the cover body and which project toward the piezoelectric substrate more than the plate-shaped cover body does.

20. The surface acoustic wave device described in claim 19, wherein the plurality of through holes is arranged in respective ones of the plurality of frame portions.
